(19) United States
(12) Patent Application Publication
(10) Pub. No.: US 2005/0249874 A1
(43) Pub. Date: Nov. 10, 2005

(54) Deposition apparatus and deposition method, and process gas supply method

(75) Inventors: Tomohisa Hoshino, Amagasaki-shi (JP); Yasuhiko Kojima, Nirasaki-shi (JP); Masahiro Shimizu, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/103,580

(22) Filed: Apr. 12, 2005

(30) Foreign Application Priority Data
Apr. 19, 2004 (JP) 2004-122501

(51) Int. Cl. C23C 16/00

(52) U.S. Cl. 427/248.1; 118/726; 118/715

(57) ABSTRACT

At the downstream side of the vaporizer, there are provided an orifice, and a pressure gage to measure a gas pressure between the vaporizer and the orifice. The measurement signal of the pressure gage 15 is inputted into a controller, and the controller controls the amount of the liquid material injected from a liquid delivery pump into the vaporizer so that the pressure measured by the pressure gage comes to a predetermined value. Backed by this, it is possible to supply the vaporized process gas into the process chamber at a predetermined flow rate.

### CROSS-REFERENCE TO THE INVENTION

This application is based upon and claims the benefit of priority from the prior Japanese Patent Application No. 2004-122501, filed on Apr. 19, 2004; the entire contents of which are incorporated herein by reference.

### BACKGROUND OF THE INVENTION

1. Field of the Invention

The present invention relates to a deposition apparatus and a deposition method that perform a film formation using a process gas obtained by vaporizing a liquid material, and a supply method of such a gas.

2. Description of the Related Art

In recent years, along with the highly improved speed and functions of integrated circuits, liquid materials or the like, which are hard to handle but have excellent material characteristics, are increasingly used as a process material. For instance, the liquid material such as a metal organic complex or the like is used in CVD, especially in ALD (Atomic Layer Deposition) and so forth.

As a method supplying the process gas from these liquid materials, there are known a bubbling method, in which a gas is injected into a reserver having a liquid material therein to vaporize the liquid material by bubbling, and a baking method, in which the reserver having the liquid material therein is heated to gasify the liquid material by evacuation. Further, for those substances that are readily pylolitically decomposed due to their raw materials having low vapor pressure, a DLI (Direct Liquid Injection) method is employed. In the DLI method, only a required amount of liquid material for a process is supplied into a vaporizer to vaporize the liquid material by the vaporizer to supply it as the process gas.

In such a DLI method, as a method to control the flow rate of the process gas, there is known one, in which the flow rate of the liquid material in flowing into the vaporizer is controlled by a liquid mass flow controller or the like, so that the flow rate of the process gas is indirectly controlled (for example, refer to Japanese Patent Application Laid-Open No. 2000-248363). Specifically, in this method, as shown in FIG. 2, the flow rate of the liquid material supplied from a reserver 1 to a vaporizer 2 is controlled by a liquid flow rate controlling mechanism 3 composed of the liquid mass flow controller or the like so as to control the flow rate of the process gas sent to a process chamber. Note that, in FIG. 2, “4” denotes a liquid valve and “5” denotes a vapor valve.

Also, as shown in FIG. 3, there is known another method, in which the flow rate of the gas vaporized in the vaporizer 2 is measured by a mass flow meter 6, and the resultant measured flow rate is fed back to a pump (conductance valve) 7 supplying the liquid material to the vaporizer 2 to thereby control the flow rate of the process gas.

However, the above-described conventional technologies have a problem of poor response since they take for example several seconds for a transition from the halted state of the process gas supply to the state capable of supplying the process gas at a constant flow rate. Moreover, such a poor response of the process gas supply forces to vent and dispose the process gas flown until the flow rate attains the constant rate, increasing a waste of materials, so that an effective use of materials are impossible. These problems become serious especially in the ALD or the like where the process gas supply is required to be performed intermittently.

### SUMMARY OF THE INVENTION

Therefore, an object of the present invention is to provide a deposition apparatus and a deposition method, and a process gas supply method, which can improve the response of process gas supply and thereby promote an effective use of materials more than ever.

In order to attain the above-stated object, a deposition apparatus according to an embodiment of the present invention is the deposition apparatus supplying a process gas obtained by vaporizing a liquid material into a process chamber to perform a deposition processing to a substrate set in the process chamber, including; a liquid material container containing the liquid material; a vaporizer generating the process gas vaporized from the liquid material; a liquid delivery mechanism supplying the liquid material to the vaporizer; an orifice provided at a downstream side of the vaporizer; a pressure detection mechanism detecting a pressure of the process gas between the vaporizer and the orifice; and a controller controlling a liquid amount delivered by the liquid delivery mechanism so that the pressure detected by the pressure detection mechanism comes to a predetermined value.

Further, a deposition method according to an embodiment of the present invention is the deposition method performing a deposition processing to a substrate set in a process chamber by supplying a liquid material contained in a liquid material container to a vaporizer by a liquid delivery mechanism, and by supplying a process gas obtained by vaporization to a process chamber, in which a flow rate of the process gas is controlled by detecting a pressure of the process gas between the vaporizer and an orifice provided at a downstream side of the vaporizer to control a liquid amount delivered by the liquid delivery mechanism so that the detected pressure value comes to a predetermined value.

Still further, a process gas supply method according to an embodiment of the present invention is the process gas supply method supplying a liquid material contained in a liquid material container to a vaporizer by a liquid delivery mechanism to supply obtained vaporized process gas to a process chamber, in which a flow rate of the process gas is controlled by detecting a pressure of the process gas between the vaporizer and an orifice provided at a downstream side of the vaporizer and by controlling the liquid amount delivered by the liquid delivery mechanism so that the detected pressure comes to a predetermined value.

Furthermore, an embodiment of the present invention is characterized in that the process gas is supplied intermittently. Moreover, an embodiment of the present invention is characterized in that the detection of the pressure of the process gas is performed in the vaporizer.

### BRIEF DESCRIPTION OF THE DRAWINGS

FIG. 1 is a view schematically showing an overall configuration of a deposition apparatus according to an embodiment of the present invention.

FIG. 2 is a view showing a configuration of a substantial part of a conventional deposition apparatus.

FIG. 3 is a view showing the configuration of the substantial part of the conventional deposition apparatus.

### DESCRIPTION OF THE EMBODIMENTS

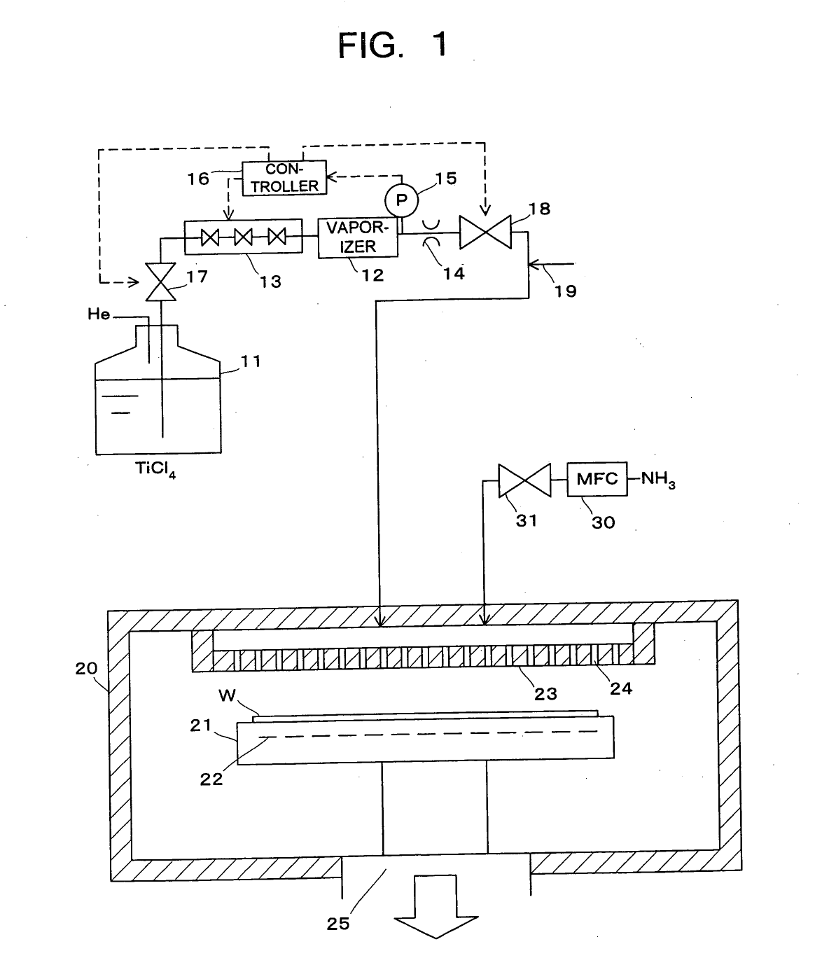

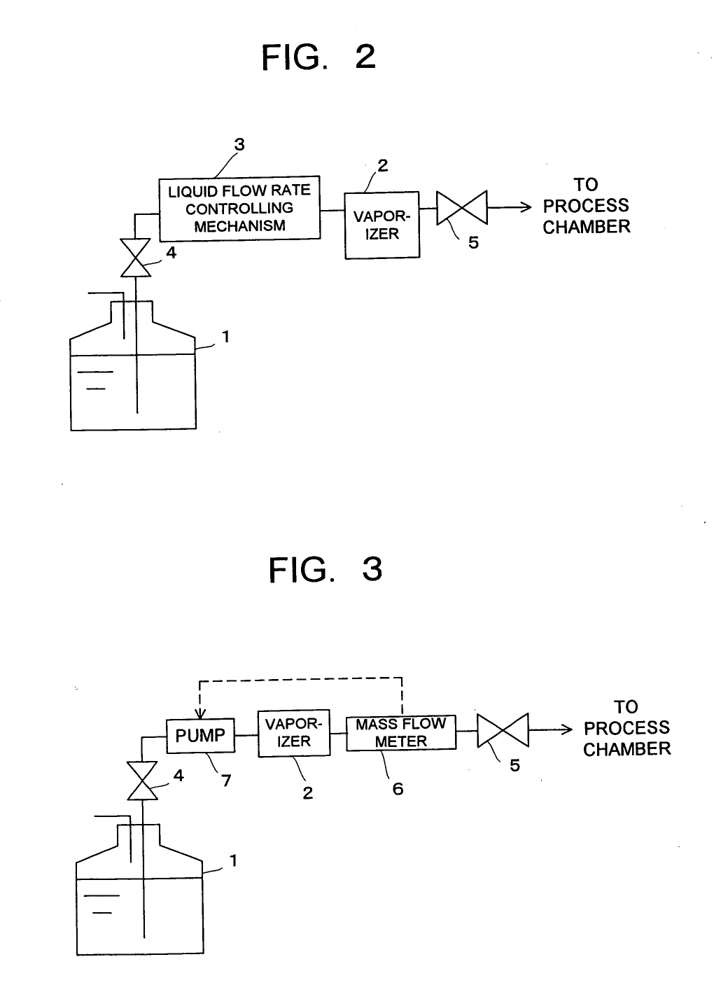

Hereinafter, details of the present invention will be described as to an embodiment with reference to the drawings. FIG. 1 shows a configuration of a deposition apparatus according to the embodiment of the present invention. In the drawing, a reserver containing a liquid material is denoted by “11”. As the liquid material, here, there is used a liquid material of a halogen family, for example, TiCl₄, SnCl₄, or the like; a liquid material of an MO family, for example, tert-butyliminotris (diethylamino) tantalum, tetraethylhafnium, trimethylaluminum, bisethylcyclopentadienylruthenium, bis(6-ethyl-2,2-dimethyl-3, 5-decanedionate) copper or the like; or a liquid material of an organic Si family, for example, tetramethylsilane, trimethylsilane, dimethyldimethoxysilane. To the reserver 11, as an example, the gas pressure of an inert gas such as He gas or the like is applied.

A vaporizer 12 vaporizing and transforming the liquid material into a process gas is connected to the reserver 11, and a liquid delivery pump 13 is inserted into between the reserver 11 and the vaporizer 12. As the liquid delivery pump 13, for example, that structured by coupling a plurality of diaphragm valves (three pieces in the example in FIG. 1) can be used. Specifically, in the liquid delivery pump 13 of such a structure, assuming that the valves are denoted by valve 1, valve 2, and valve 3 from the left in FIG. 1, the liquid delivery is realized by repeating the acts of; opening the valve 1, opening the valve 2,→closing the valve 1 and→opening the valve 3, closing the valve 2, and→closing the valve 3, in which the flow rate of the delivered liquid can be controlled by controlling the speed to repeat and/or the duty cycle for the repetition. Note that a conductance valve may also be used in replacement of the liquid delivery pump 13.

At a downstream side of the vaporizer 12, there is provided an orifice 14, and a pressure gage 15 to measure a gas pressure between the vaporizer 12 and the orifice 14. It is designed that a measurement signal by the pressure gage 15 is inputted into a controller 16, and the controller 16 controls the flow rate of the liquid material injected from the liquid delivery pump 13 into the vaporizer 12 so that the pressure measured by the pressure gage 15 comes to a predetermined value. Note that, in FIG. 1, “17” denotes a liquid valve and “18” denotes a vapor valve, of which open/close are also controlled by the controller 16. Note that, the pressure gage 15 is designed to measure the pressure at the downstream side of the vaporizer 12 in FIG. 1, whereas it is possible to design that the pressure gage 15 measures an inside pressure of the vaporizer 12.

In the present embodiment, the flow rate of the process gas introduced into a process chamber 20 via the orifice 14 and the vapor valve 18 is controlled to be a predetermined flow rate by controlling the gas pressure between the vaporizer 12 and the orifice 14 to be a predetermined value as described above. Backed by this, in the state of halting the process gas supply by closing the vapor valve 18, the process gas at a predetermined flow rate can be supplied immediately (for example, approximately within 0.1 second) after opening the vapor valve 18, so that the response can be improved as compared with conventional ones. Note that, in FIG. 1, “19” denotes a carrier gas flow path to introduce a carrier gas into a process gas flow path.

In order to control the flow rate of a liquid material that is readily pyrolytically decomposed due to its low vapor pressure, a DLI (Direct Liquid Injection) method supplying a required amount of material for a process and vaporizing it in the vaporizer has been considered to be effective, however, the conventional DLI method has a not-yet-vaporized material between a liquid mass flow controller and the vaporizer due to a lot of dead space, sometimes causing a disagreement between the flow rate controlled by the liquid mass flow controller and the gas flow rate vaporized in the vaporizer, so that it is difficult to supply the material at a flow rate required for the process into the process chamber with high accuracy.

Further, in the mass flow controller, which heats a part of the gas flow path to make use of the temperature difference of a heater between before and after the heating as the temperature difference is in parallel with the mass flow rate, the response speed depends on a heat capacity, causing problems of low operating speed as well as long transient response. On the contrary, the present embodiment is configured to monitor the pressure of the material vaporized by the vaporizer, where the pressure gage detects the gas pressure within a time frame of 0.01 second or shorter, allowing a significant improvement of the transient response performance.

In a process chamber 20, there are provided a stage 21 to mount a substrate such as a semiconductor wafer W thereon, and, in the stage 21, a heater 22 to heat the semiconductor wafer W up to a predetermined temperature. Above the stage 21, a shower head 23 having a lot of gas supply holes 24 is provided so as to face the stage 21.

Further, at a bottom of the process chamber 20, an exhaust port 25 is provided, allowing the process chamber 20 to discharge gas for example by a not-shown exhaust mechanism composed of a turbo molecular pump and a dry pump, or the like so that the inside thereof has a predetermined pressure.

The above-described shower head 23 includes an introduction mechanism to introduce a process gas such as NH₃, which is other than the process gas valorized from the previously-described liquid material such as TiCl₄. The introduction mechanism of the process gas is composed of an MFC (mass flow controller) 30, an open/close valve 31, and so forth.

In the deposition apparatus of the above-described configuration, a substrate to be subject to a deposition process, for example, the semiconductor wafer W, is mounted on the stage 21 in the process chamber 20 by a not-shown open/close mechanism, and the semiconductor wafer W is heated up to a predetermined temperature (for example, up to 200° C. to 650° C.) by the heater 22.

Along therewith, the process gas generated by vaporizing the liquid material such as TiCl₄ in the reserver 11 by the vaporizer 12, and the other process gas such as NH₃ are supplied from the shower head 23 into the process chamber 20 at a predetermined flow rate, and the gas is discharged from the exhaust port 25 to thereby form a film such as of TiN on the semiconductor wafer W.

At this time, the amount of the liquid material delivered from the liquid delivery pump 13 and injected into the vaporizer 12 is controlled so that the pressure measured by the pressure gage 15 comes to a predetermined value while the vapor valve 18 is in the state of being closed, and the vapor valve 18 is opened in that state. In the course of the deposition process, the controller 16 controls the liquid amount delivered from the liquid delivery pump 13 and injected into the vaporizer 12 so that the pressure measured by the pressure gage 15 is kept at a predetermined value. Backed by this, it is possible to supply the process gas such as TiCl₄ into the process chamber 20 at a flow rate constantly kept at a certain level with accuracy in quick response to the opening of the vapor valve 18. Further, at this time, if necessary, a carrier gas is introduced into the process gas flow path from the carrier gas flow path 19 to deliver the process gas by the carrier gas. Moreover, by opening the open/close valve 31, the other process gas such as NH₃ is supplied into the process chamber 20 while controlling the flow rate thereof to a predetermined flow rate by the MFC 30.

When a film of TiN or the like having a predermined film thickness is formed on the semiconductor wafer W, the vapor valve 18 and the open/close valve 31 are closed together to halt the supply of the process gas to thereby cease the deposition process, and the semiconductor wafer W is ejected from the process chamber 20 to complete the processing.

Furthermore, when growing an atomic layer by ALD (Atomic Layer Deposition), the process gas is supplied into the process chamber 20 intermittently by a predetermined amount by way of opening/closing the vapor valve 18 and the open/close valve 31 intermittently. Even in such a case, according to the present embodiment, the process gas can be supplied at a predetermined flow rate immediately after the opening of the vapor valve in quick response thereto, allowing an effective film formation in a short period of time. Specifically, if it takes a long time from the opening of the vapor valve until the flow rate of the process gas attains a predetermined flow rate, there arises a need to dispose the process gas used until the flow rate attains the predetermined flow rate into a drain, or the like. However, such a waste of the process gas can be eliminated and the entire process time can be reduced additionally thereto.

Note that, in the above-described embodiment, the description has been given for the case where the present invention is applied to a TiN film formation processing using TiCl₄ and NH₃, however, the present invention may surely apply to other processing such as the deposition processing using the other process gas, in similar fashion.

As has been described above, according to the deposition apparatus and the deposition method, and the process gas supply method of the present invention, the response of the process gas supply can be improved more than before, so that the effective use of the materials can be supported.

1. A deposition apparatus supplying a process gas obtained by vaporizing a liquid material into a process chamber to perform a deposition processing to a substrate set in the process chamber, comprising;
a liquid material container containing the liquid material;
a vaporizer generating the process gas vaporized from the liquid material;
a liquid delivery mechanism supplying the liquid material to said vaporizer;
an orifice provided at a downstream side of said vaporizer;
a pressure detection mechanism detecting a pressure of the process gas between said vaporizer and said orifice; and
a controller controlling a liquid amount delivered by said liquid delivery mechanism so that the pressure detected by said pressure detection mechanism comes to a predetermined value.

2. A deposition apparatus as set forth in claim 1,
wherein the process gas is supplied intermittently.

3. A deposition apparatus as set forth in claim 1,
wherein said pressure detection mechanism is configured to detect a pressure inside said vaporizer.

4. A deposition method performing a deposition processing to a substrate set in a process chamber by supplying a liquid material contained in a liquid material container to a vaporizer by a liquid delivery mechanism, and by supplying a process gas obtained by vaporization to a process chamber,
wherein a flow rate of the process gas is controlled by detecting a pressure of the process gas between the vaporizer and an orifice provided at a downstream side of the vaporizer to control a liquid amount delivered by the liquid delivery mechanism so that the detected pressure value comes to a predetermined value.

5. A deposition method as set forth in claim 4,
wherein the process gas is supplied intermittently.

6. A deposition method as set forth in claim 4,
wherein said detection of the pressure of the process gas is performed in the vaporizer.

7. A process gas supply method supplying a liquid material contained in a liquid material container to a vaporizer by a liquid delivery mechanism to supply obtained vaporized process gas to a process chamber,
wherein a flow rate of the process gas is controlled by detecting a pressure of the process gas between the vaporizer and an orifice provided at a downstream side of the vaporizer and by controlling the liquid amount delivered by the liquid delivery mechanism so that the detected pressure comes to a predetermined value.

8. A process gas supply method as set forth in claim 7,
wherein the process gas is supplied intermittently.

9. A process gas supply method as set forth in claim 7,
wherein said detection of the pressure of the process gas is performed in the vaporizer.
